(19) United States
(12) Patent Application Publication
(10) Pub. No.: US 2015/0122180 A1
(43) Pub. Date: May 7, 2015

(54) SUBSTRATE TRANSFER APPARATUS AND THIN FILM DEPOSITION APPARATUS HAVING THE SAME

(71) Applicant: Samsung Display Co., Ltd., Yongin-City (KR)

(72) Inventors: Yun-Ho CHANG, Bucheon-si (KR); Hyuck-Mok KWON, Hwaseong-si (KR)

(21) Appl. No.: 14/520,548

(22) Filed: Oct. 22, 2014

(30) Foreign Application Priority Data
Nov. 7, 2013 (KR) 10-2013-0134610

(51) Int. Cl. C23C 16/458; H01L 21/677

(52) U.S. Cl. CPC C23C 16/4585; H01L 21/67709
USPC 118/729; 414/749.2

(57) ABSTRACT

A substrate transfer apparatus includes a guide rail, a carrier, a magnetic levitation unit, and a transferring unit. The guide rail is in a vacuum evacuable chamber. The carrier may carry a substrate and may be linearly movable along the guide rail. The magnetic levitation unit is configured to generate a magnetic levitation force between the guide rail and the carrier. The transferring unit is configured to generate a momentum for linearly transferring the carrier and includes a plurality of first transferring magnetic material members on an upper surface of the carrier, a plurality of second transferring magnetic material members over the carrier and spaced apart from the first transferring magnetic material members, and a plurality of containers in which the plurality of second transferring magnetic material members is respectively disposed.

This application claims priority to Korean patent Application No. 10-2013-0134610, filed on Nov. 7, 2013, and all the benefits accruing therefrom under 35 U.S.C. §119, the disclosure of which is hereby incorporated by reference herein in its entirety.

### BACKGROUND

1. Field

Exemplary embodiments of the invention relate to a substrate transfer apparatus and a thin film deposition apparatus having the substrate transfer apparatus. More particularly, exemplary embodiments of the invention relate to a substrate transfer apparatus for transferring a substrate using a carrier for carrying the substrate thereon and a thin film deposition apparatus having the substrate transfer apparatus.

2. Description of the Related Art

A display device may be manufactured by various processes such as a thin film deposition process, etc. Here, the processes may be performed using a thin film deposition apparatus including process chambers. For example, the thin film deposition apparatus may be divided into a cluster type and an inline type in accordance with an arrangement of the process chambers. The thin film deposition apparatus having the inline type may be advantageous because the thin film deposition apparatus having the inline type may be not restricted relative to an installation space thereof, when compared with the thin film deposition apparatus having the cluster type.

### SUMMARY

Processing chambers of a thin film deposition apparatus having the inline type may be arranged in series. In the series arrangement of the processing chambers, a substrate transfer apparatus may be employed to the thin film deposition apparatus for transferring a substrate to each of the process chambers. The substrate transfer apparatus may be divided into a contact type and a non-contact type in accordance with a transferring method of the substrate. The substrate transfer apparatus having the contact type may cause pollution due to particles generated while transferring the substrate (e.g., pollution of a substrate, pollution of a clean room). Alternatively, the substrate transfer apparatus having the non-contact type may solve the pollution, damage to parts of the substrate transfer apparatus caused by a friction and a noise, so that the substrate transfer apparatus having the non-contact type has been researched and developed.

The substrate transfer apparatus having the non-contact type (e.g., magnetic levitation type) may include a carrier on which a substrate is carried, a magnetic levitator (otherwise referred to herein as a magnetic levitation unit) that magnetically levitates the carrier, a transferor (otherwise referred to herein as a transferring unit) that transfers the carrier, etc. However, the magnetic levitation unit may levitate the carrier using a permanent magnet, so that the magnetic levitation unit may not accurately control the carrier. That is, the carrier may be vibrated and/or a speed of the carrier may be undesirably changed while magnetically levitating the carrier. Therefore, the carrier may not sequentially transfer the substrates because the transferring unit has wirings that receive a driving power.

One or more exemplary embodiment provides a substrate transfer apparatus capable of accurately and sequentially transferring a substrate.

One or more exemplary embodiment provides a thin film deposition apparatus including the substrate transfer apparatus.

According to an exemplary embodiment of the invention, there is provided a substrate transfer apparatus including a guide rail, a carrier, a magnetic levitation unit, and a transferring unit. The guide rail is in a vacuum evacuable chamber. The carrier to which a substrate may be mounted, is configured to be linearly movable along the guide rail. The magnetic levitation unit is configured to generate a magnetic levitation force between the guide rail and the carrier. The transferring unit is configured to generate a momentum for linearly transferring the carrier, and includes a plurality of first transferring magnetic material members on an upper surface of the carrier, a plurality of second transferring magnetic material members over the carrier and spaced apart from the first transferring magnetic material members, and a plurality of containers in which the second transferring magnetic material members is respectively disposed.

In exemplary embodiments, the guide rail may extend in a first direction and may include a first rail, and a second rail spaced apart from the first rail in a second direction perpendicular to the first direction, where the first and second rails define a space in which the carrier linearly moves along the guide rail. Each of the first and the second rails may include first protrusion portions spaced apart in a third direction perpendicular to the first and second directions, and a first recess portion defined between the spaced apart first protrusion portions, each of the first protrusion portions and the first recess portion extended in the first direction.

In exemplary embodiments, the carrier may include first side second protrusion portions protruded towards the first rail, and adjacent to each other in the third direction, second side second protrusion portions protruded towards the second rail, and adjacent to each other in the third direction, and first and second side second recess portions defined between the adjacent first side second protrusion portions and the adjacent second side second protrusion portions, respectively. Each of the second protrusion portions and the second recess portions may be extended in the first direction. A first side second protrusion portion and a second side second protrusion portion of the carrier may engage with the first recess portion of the first rail and the first recess portion of the second rail, respectively. The first side second recess portion and the second side second recess portion of the carrier may engage with a first protrusion portion of the first rail and a first protrusion portion of the second rail, respectively.

In exemplary embodiments, the carrier may additionally include a carrier body, and a substrate plate which is in a lower portion of the carrier body and holds the substrate.

In exemplary embodiments, the first protrusion portions of the guide rail may overlap the second protrusion portions of the carrier. The magnetic levitation unit may include a plurality of first levitating magnetic material members in the first protrusion portions of the guide rail and a plurality of second levitating magnetic material members in the second protrusion portions of the carrier. The plurality of second levitating magnetic material members may respectively face the plurality of first levitating magnetic material members in the guide rail.

In exemplary embodiments, each of the first levitating magnetic material members may include stainless steel.

In exemplary embodiments, each of the second levitating magnetic material members may include an electromagnet or a permanent magnet.

In exemplary embodiments, the magnetic levitation unit may additionally include a first sensor which is in the guide rail and configured to control a relative position between the first levitating magnetic material members and the second levitating magnetic material members.

In exemplary embodiments, the transferring unit may additionally include a piping member which is connected to a container among the plurality of containers, extended to an outside of the chamber and maintains the container at atmospheric pressure.

In exemplary embodiments, the substrate transfer apparatus may further include a wiring which is connected to the second transferring magnetic material member in the container, via the piping member, and through which a driving power may be applied to the second transferring magnetic material in the container from an external power supply.

In exemplary embodiments, the transferring unit may additionally include a second sensor which is in a container among the plurality of containers and configured to control a relative position between the first transferring magnetic material members and the second transferring magnetic material members.

In exemplary embodiments, each of the first transferring magnetic material members may include a permanent magnet.

In exemplary embodiments, each of the first transferring magnetic material members may have different polarities.

In exemplary embodiments, each of the second transferring magnetic material members may include an electromagnet.

In exemplary embodiments, the second transferring magnetic materials may be spaced apart from each other along the guide rail and in the first direction, and the carrier may overlap at least three second transferring magnetic material members in the first direction, in a top plan view.

According to another exemplary embodiment of the invention, there is provided a thin film deposition apparatus including a vacuum evacuable processing chamber, a guide rail, a carrier, a magnetic levitation unit and a transferring unit. The vacuum evacuable processing chamber defines a space in which a thin film is deposited on a substrate. The guide rail is in the processing chamber. The carrier is configured to carry the substrate and linearly move along the guide rail. The magnetic levitation unit is configured to generate a magnetic levitation force between the guide rail and the carrier. The transferring unit is configured to generate a momentum for linearly transferring the carrier, and includes a plurality of first transferring magnetic material members on an upper surface of the carrier, a plurality of second transferring magnetic material members over the carrier and spaced apart from the first transferring magnetic material members, and a plurality of containers in which the plurality of second transferring magnetic material members is respectively disposed.

In exemplary embodiments, the thin film deposition apparatus may additionally include a loading chamber in which the substrate is loaded into the thin film deposition apparatus, the loading chamber coupled to the processing chamber, and an unloading chamber from which the substrate is unloaded from the thin film deposition apparatus, the unloading chamber coupled to the processing chamber.

In exemplary embodiments, the transferring unit may additionally include a piping member which is connected to a container among the plurality of containers. The piping member may be connected to an outside of the processing chamber and maintain the container at atmospheric pressure.

In exemplary embodiments, the substrate transfer apparatus may further include a wiring which is connected to the second transferring magnetic material in the container, via the piping member, and through which a driving power may be applied to the second transferring magnetic material in the container from an external power supply.

In exemplary embodiments, the second transferring magnetic material members may be spaced apart from each other along the guide rail and in the first direction, and the carrier may overlap three second transferring magnetic material members in the first direction, in a top plan view.

Therefore, in one or more exemplary embodiment of a substrate transfer apparatus and a thin film deposition apparatus having the substrate transfer apparatus, the substrate transfer apparatus includes the magnetic levitation unit which is configured to magnetically levitate the carrier with respect to the guide rail and the transferring unit which transfers the carrier, both in the chamber selectively having the vacuum state or the atmospheric pressure state. Accordingly, the substrate transfer apparatus may accurately and sequentially transfer the substrate. That is, the substrate transfer apparatus may reduce or effectively prevent the carrier from being vibrated, and the substrate transfer apparatus may reduce or effectively prevent a speed of the carrier from being changed. As a result, the substrate transfer apparatus may efficiently transfer the substrate.

In addition, the thin film deposition apparatus may transfer the substrate to each of the chambers (e.g., processing chambers having the vacuum state) using the substrate transfer apparatus. As a result, the thin film deposition apparatus may uniformly deposit a thin film on the substrate.

### BRIEF DESCRIPTION OF THE DRAWINGS

Illustrative, non-limiting exemplary embodiments will be more clearly understood from the following detailed description taken in conjunction with the accompanying drawings.

FIG. 1 is a cross-sectional view illustrating an exemplary embodiment of a substrate transfer apparatus in accordance with the invention.

FIG. 2 is a side cross-sectional view illustrating the substrate transfer apparatus of FIG. 1.

FIG. 3 is a perspective view illustrating a portion of the substrate transfer apparatus of FIG. 1.

FIG. 4 is a cross-sectional perspective view of portion A of FIG. 1.

FIG. 5 is a perspective view illustrating an exemplary embodiment of a carrier separated from a guide rail of the substrate transfer apparatus of FIG. 1.

FIG. 6 is a side cross-sectional view illustrating an exemplary embodiment of a transferring unit of the substrate transfer apparatus of FIG. 1.

FIG. 7 is a side cross-sectional view illustrating an exemplary embodiment of a thin film deposition apparatus in accordance with the invention.

### DETAILED DESCRIPTION

The invention is described more fully hereinafter with reference to the accompanying drawings, in which exemplary embodiments of the invention are shown. This invention may, however, be embodied in many different forms and should not be construed as limited to the exemplary embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on,” “connected to” or “coupled to” another element or layer, the element or layer can be directly on, connected or coupled to another element or layer or intervening elements or layers. In contrast, when an element is referred to as being “directly on,” “directly connected to” or “directly coupled to” another element or layer, there are no intervening elements or layers present. As used herein, connected may refer to elements being physically and/or electrically connected to each other. Like numbers refer to like elements throughout. As used herein, the term “and/or” includes any and all combinations of one or more of the associated listed items.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the invention.

Spatially relative terms, such as “lower,” “under,” “above,” “upper” and the like, may be used herein for ease of description to describe the relationship of one element or feature to another element(s) or feature(s) as illustrated in the figures. It will be understood that the spatially relative terms are intended to encompass different orientations of the device in use or operation, in addition to the orientation depicted in the figures. For example, if the device in the figures is turned over, elements described as “under” relative to other elements or features would then be oriented “above” relative to the other elements or features. Thus, the exemplary term “under” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises,” “comprising,” “includes” and/or “including,” when used in this specification, specify the presence of stated features, integers, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10%, 5% of the stated value.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Illustrative, non-limiting exemplary embodiments will be more clearly understood from the following detailed description taken in conjunction containing the accompanying drawings.

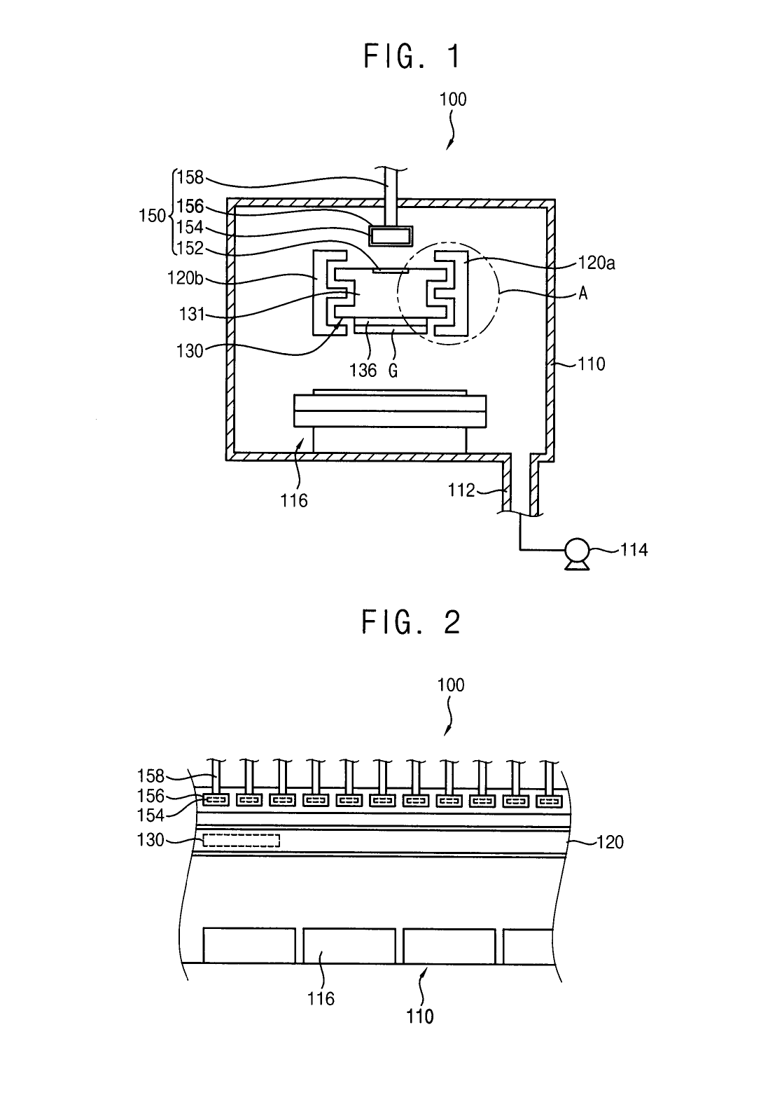

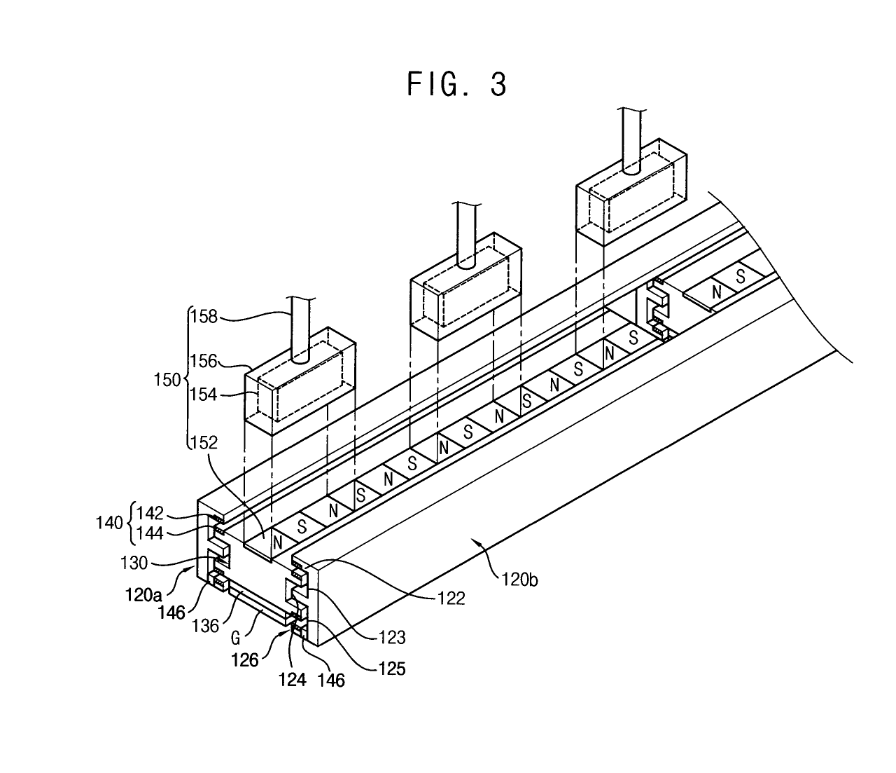

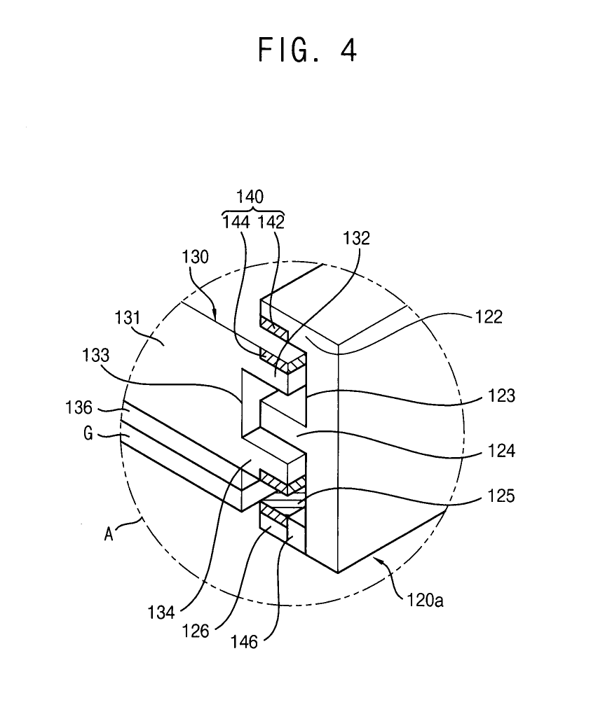

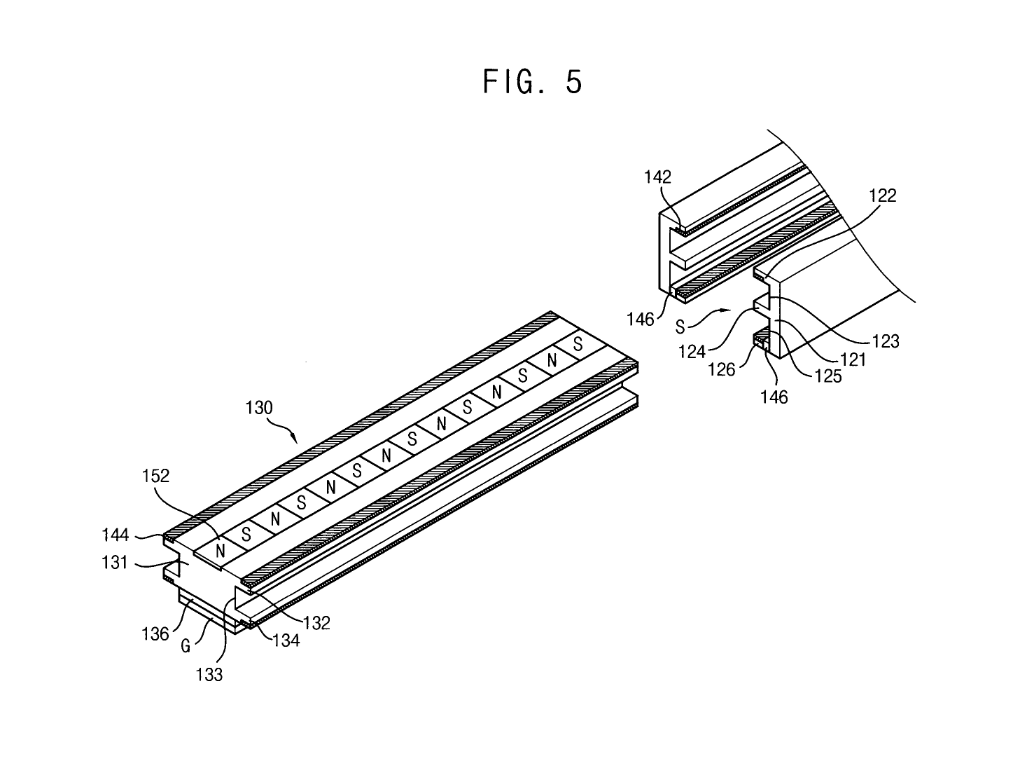

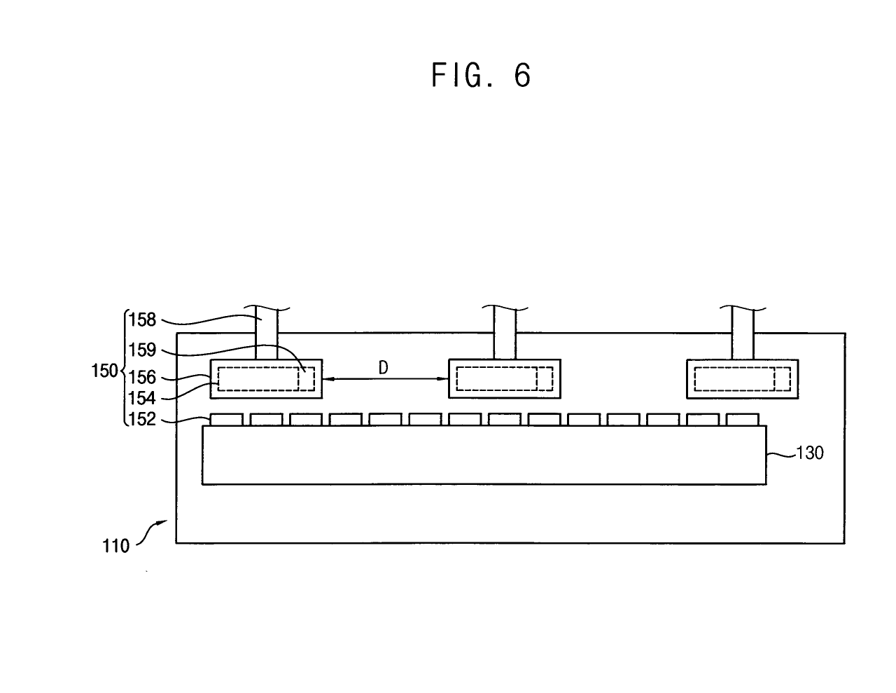

FIG. 1 is a cross-sectional view illustrating an exemplary embodiment of a substrate transfer apparatus in accordance with the invention. FIG. 2 is a side cross-sectional view illustrating the substrate transfer apparatus of FIG. 1. FIG. 3 is a perspective view illustrating a portion of the substrate transfer apparatus of FIG. 1. FIG. 4 is a cross-sectional perspective view illustrating portion A in FIG. 1. FIG. 5 is a perspective view illustrating an exemplary embodiment of a carrier separated from a guide rail of the substrate transfer apparatus of FIG. 1. FIG. 6 is a side cross-sectional view illustrating an exemplary embodiment of a transferring unit of the substrate transfer apparatus of FIG. 1.

Referring FIGS. 1 to 6, a substrate transfer apparatus 100 may include a guide rail 120 provided in a chamber 110, a carrier 130 linearly movable along the guide rail 120, a carrier supporting member such as a magnetic levitator 140 (otherwise referred to herein as a magnetic levitation unit 140) configured to generate a magnetic levitation force between the guide rail 120 and the carrier 130, and a transferor 150 (otherwise referred to herein as a transferring unit 150) configured to generate a momentum for linearly transferring the carrier 130.

In exemplary embodiments, the substrate transfer apparatus 100 may be positioned in the chamber 110 of a thin film deposition apparatus for forming a thin film on a substrate G, to transfer the substrate G. In an exemplary embodiment, for example, the substrate G may correspond to a glass substrate for manufacturing a liquid crystal display device, an organic light emitting display device, a flat panel display device, etc. The chamber 110 may be exhausted and depressurized to a desired vacuum level by a vacuum pump 114 through a gas exhaust port 112. Here, the vacuum pump 114 may be connected to a lower portion of the chamber 110. In addition, at least one an evaporation source 116 may be provided in the lower portion of the chamber 110. In an exemplary embodiment, for example, the evaporation source 116 may include a material to be deposited on the substrate G, and the material from the evaporation source 116 may be sprayed on the substrate G in an exemplary embodiment of forming a thin film. The evaporation source 116 may extend along a first direction.

The guide rail 120 may be arranged in the chamber 110. The guide rail 120 may include a first rail 120a, and a second rail 120b opposite to the first rail 120a, in a second direction perpendicular to the first direction. Here, the first rail 120a and the second rail 120b may define a space S through and in which the carrier 130 is transferred. The first rail 120a and the second rail 120b may be substantially parallel to each other, and may extend (e.g., be elongated) along the first direction respectively.

The carrier 130 may be translated in the space S between the first rail 120a and the second rail 120b to be linearly movable along the guide rail 120 (e.g., in the first direction). In an exemplary embodiment, for example, the carrier 130 may include aluminum (Al), titanium (Ti), ceramic, engineering plastic, etc.

Each of the first rail 120a and the second rail 120b may include at least one a first protrusion portion and at least one a first recess portion. As illustrated in FIGS. 4 and 5, the first rail 120a may include a rail body 121 that extends along the first direction, a first upper protrusion portion 122 protruding from an upper portion of the rail body 121, a first central protrusion portion 124 protruding from the middle portion of the rail body 121, and a first lower protrusion portion 126 protruding from a lower portion of the rail body 121. A first upper recess portion 123 may be defined between the first upper protrusion portion 122 and the first central protrusion portion 124, where the first upper protrusion portion 122 and the first central protrusion portion 124 are adjacent to each other in a third direction perpendicular to the first and second directions. A first lower recess portion 125 may be defined between the first central protrusion portion 124 and the first lower protrusion portion 126, where the first central protrusion portion 124 and the first lower protrusion portion 126 are adjacent to each other in the third direction perpendicular to the first and second directions. The second rail 120b may be substantially the same as the first rail 120a, and thus, any further repetitive explanations thereof will be omitted.

The carrier 130 may include a second protrusion portion and a second recess portion which are engaged with opposing first recess portions and first protrusion portions of the facing first and second rails 120a and 120b, respectively. As illustrated in FIGS. 4 and 5, the carrier 130 may include a carrier body 131 that moves between the first rail 120a and the second rail 120b, a second upper protrusion portion 132 protruding from an upper portion of the carrier body 131, and a second lower protrusion portion 134 protruding from an lower portion of the carrier body 131. Here, a second recess portion 133 may be defined between the second upper protrusion portion 132 and the second lower protrusion portion 134, where the second upper protrusion portion 132 and the second lower protrusion portion 134 are adjacent to each other in the third direction perpendicular to the first and second directions.

Thus, the second upper protrusion portion 132 of the carrier 130 may be received in the first upper recess portion 123 of the first rail 120a, and the second lower protrusion portion 134 of the carrier 130 may be received in the first lower recess portion 125 of the first lower recess portion 125 of the first rail 120a.

Additionally, a lower surface of the first upper protrusion portion 122 of the first rail 120a may face an upper surface of the second upper protrusion portion 132 of the carrier 130. An upper surface of the first lower protrusion portion 126 of the first rail 120a may face a lower surface of the second lower protrusion portion 134 of the carrier 130.

Further, the carrier 130 may further include a substrate plate 136 which is provided in a lower portion of the carrier body 131 and to which the substrate G is mounted. The carrier 130 may hold and mount the substrate G using the substrate plate 136. In an exemplary embodiment, for example, the substrate plate 136 may include a fixing member such as clamp, chuck, etc.

In exemplary embodiments, the magnetic levitation unit 140 may suspend the carrier 130 using the guide rail 120 which functions as a magnetic bearing.

The magnetic levitation unit 140 may include a plurality of first levitating magnetic materials 142 (also referred to as first levitating magnetic material members) provided in the first protrusion portions of the guide rails 120a and 120b, and a plurality of second levitating magnetic materials 144 (also referred to as second levitating magnetic material members) provided in the second protrusion portions of the carrier 130 corresponding to the first protrusion portions of the guide rails 120a and 120b.

As illustrated in FIGS. 4 and 5, the first levitating magnetic materials 142 may be provided on a lower surface of the first upper protrusion portion 122 of the first rail 120a and an upper surface of the first lower protrusion portion 126 of the first rail 120a, respectively. The second levitating magnetic materials 144 may be provided on an upper surface of the second upper protrusion portion 132 of the carrier 130 corresponding to the first upper protrusion portion 122 and on a lower surface of the second lower protrusion portion 134 of the carrier 130 corresponding to the first lower protrusion portion 126, respectively.

In an exemplary embodiment, for example, each of the first levitating magnetic materials 142 may include stainless steel (“SUS”). Hence, the first levitating magnetic materials 142 may have a flat upper surface to thereby efficiently control a magnetic force with respect to the second levitating magnetic materials 144. However, the material of the first levitating magnetic material 142 is not limited thereto. In another exemplary embodiment, for example, the first levitating magnetic material 142 may include a magnetic metal.

In exemplary embodiments, the first levitating magnetic materials 142 may be held recessed from the lower surface of the first upper protrusion portion 122 of the first rail 120a and from the upper surface of the first lower protrusion portion 126 by a fixing member such as a screw, respectively. Alternatively, the first levitating magnetic materials 142 may be attached to a recess extending from the lower surface of the first upper protrusion portion 122 of the first rail 120a and a recess extending from the upper surface of the first lower protrusion portion 126 such as by using an adhesive member, respectively.

In addition, the magnetic levitation unit 140 may further include a first hall sensor 146 which is configured to control a relative position between the first levitating magnetic materials 142 and the second levitating magnetic materials 144. In an exemplary embodiment, the magnetic levitation unit 140 may include a photo-curable material or a thermosetting material therein. Thus, damage to the first hall sensor 146 may be reduced or effectively prevented, so that the first hall sensor 146 may be used to efficiently control a relative position between the first levitating magnetic materials 142 and the second levitating magnetic materials 144. Therefore, the first hall sensor 146 may accurately control a position of the carrier 130 while transferring the carrier 130.

The first and/or second levitating magnetic material 142 and 144 may be a single, unitary, indivisible member disposed on the carrier 130 and the rails 120a and 120b, respectively. The levitating magnetic material member may have substantially a same length as the respective carrier 130 or rail 120.

Accordingly, the magnetic levitation unit 140 may be positioned within the chamber 110 to magnetically suspend the carrier 130. Here, the magnetic levitation unit 140 may magnetically levitate the carrier 130 while transferring the carrier 130 using an attraction force between the first levitating magnetic materials 142 and the second levitating magnetic materials 144. In an exemplary embodiment, for example, in levitating the carrier 130 with respect to the guide rails 120a and 120b, the carrier 130 may be spaced apart from the guide rails 120a and 120b. A spacing distance between the guide rail 120 and the carrier 130 may be about 600 micrometers (μm) but is not limited thereto.

A magnetic levitation unit of a conventional substrate transfer apparatus levitates a carrier using an attraction force and/or a repulsive force generated from permanent magnets having different polarities. In addition, the magnetic levitation unit may have a structure in which first through N-th magnetic levitation units are arranged along a moving direction of the carrier, where N is an integer larger than or equal to 2. Thus, the carrier is vibrated and a speed of the carrier is changed caused by a tolerance between the magnetic levitation units.

In consideration of these problems, in one or more exemplary embodiment according to the invention, the first levitating magnetic materials 142, the second levitating magnetic materials 144 and the first hall sensor 146 of the magnetic levitation unit 140 may be sequentially arranged along the moving direction of the carrier 130 in which the substrate G is transferred. Thus, the magnetic levitation unit 140 may detect precisely a relative position between the first levitating magnetic materials 142 and the second levitating magnetic materials 144 to accurately control a position of the carrier 130. In addition, the magnetic levitation unit 140 may levitate the carrier 130 by using the attraction force between the first levitating magnetic materials 142 and the second levitating magnetic materials 144 while the carrier 130 is transferred.

In one or more exemplary embodiment according to the invention, the substrate transfer apparatus 100 may generate the magnetic force to lift the carrier 130 carrying the substrate G thereon using the first levitating magnetic materials 142 including SUS and the second levitating magnetic materials 144 including coils. Accordingly, the substrate transfer apparatus 100 may accurately control the magnetic force compared with the conventional substrate transfer apparatus. That is, in the substrate transfer apparatus 100 according to exemplary embodiments, the carrier 130 may be prevented from being vibrated, and a speed of the carrier 130 may be prevent from being changed. As a result, the substrate transfer apparatus 100 may precisely transfer the substrate.

In exemplary embodiments, the transferring unit 150 may linearly move the magnetically levitated carrier 130. As illustrated in FIGS. 3 and 6, the transferring unit 150 may include a plurality of first transferring magnetic materials 152 (also referred to as first transferring magnetic material members) provided on an upper surface of the carrier 130, a plurality of second transferring magnetic materials 154 (also referred to as second transferring magnetic material members) disposed over the carrier 130 and spaced apart from the first transferring magnetic materials 152, and a plurality of containers 156 in which the second transferring magnetic materials 154 are respectively disposed.

Referring to FIG. 2, the containers 156 may be arranged above the guide rail 120 in the first direction. The containers 156 may be configured to receive the second transferring magnetic materials 154.

The transferring unit 150 may further include a piping member 158 connected to the container 156. The piping member 158 may be connected to an element (not shown) outside of the chamber 110, and extend into the chamber 110. Thus, the piping member 158 may maintain the container 156 at an atmospheric pressure. In an exemplary embodiment, for example, when the second transferring magnetic material 154 includes an electromagnet, a wiring through which a driving power is applied to the second transferring magnetic material 154 from an external power supply, may be connected to the second transferring magnetic material 154 through the piping member 158 from the outside of the chamber 110. The container 156 may include a magnetically permeable material. In an exemplary embodiment, for example, the magnetically permeable material may be cobalt (Co), nickel (Ni), iron (Fe), etc.

In an exemplary embodiment, the first transferring magnetic materials 152 may include a plurality of permanent magnets having different polarities, indicated by ‘N’ and ‘S’ in FIG. 3 and FIG. 5. The plurality of permanent magnets may be alternately arranged on the upper surface of the carrier 130 in the first direction, to collectively define a first transferring magnetic material 152 member. Each of the second transferring magnetic materials 154 may include an electromagnetic coil.

As illustrated in FIG. 6, the second transferring magnetic materials 154 may be arranged over the first transferring magnetic materials 152 and may be spaced apart from each other by a predetermined distance D along the first direction. At least three second transferring magnetic materials 154 may overlap with end portions and the middle portion, respectively, of the carrier 130 at a specific point when the carrier 130 is transferred. That is, when the carrier 130 moves along the guide rail 120 in the first direction, the carrier 130 may be overlapped with the at least three second transferring magnetic materials 154 when view in a plan view such as a top plan view.

Thus, a difference between a maximum value and a minimum value of an attraction force between the first transferring magnetic materials 152 and the second transferring magnetic materials 154 may be decreased. Here, a section having the maximum value of an attraction force between the first transferring magnetic materials 152 and the second transferring magnetic materials 154 may correspond to a section in which the second transferring magnetic materials 154 is positioned directly over the first transferring magnetic materials 152, and a section having the minimum value of the attraction force between the first transferring magnetic materials 152 and the second transferring magnetic materials 154 may correspond to a section in which the second transferring magnetic materials 154 is not positioned over the first transferring magnetic materials 152. Accordingly, a vibration of the carrier 130 may be reduced or removed.

In exemplary embodiments, the transferring unit 150 may further include a second hall sensor 159 that controls a relative position between the first transferring magnetic materials 152 and the second transferring magnetic materials 154. Thus, damage to the second hall sensor 159 may be reduced or effectively prevented, so that the second hall sensor 159 may efficiently control a relative position between the first transferring magnetic materials 152 and the second transferring magnetic materials 154.

A transferring unit of a conventional substrate transfer apparatus is located within a chamber, and a wiring which applies a power to the transferring unit, is located in the chamber, so that a carrier may be not efficiently transferred. In consideration of these problems, in one or more exemplary embodiment according to the invention, the transferring unit 150 may be located within the chamber 110 having the atmospheric pressure. Therefore, the transferring unit 150 may accurately control the carrier 130.

In addition, the wiring for operating the transferring unit 150 may be connected to the outside of the chamber 110 by the piping member 158, so that the transferring unit 150 may have a simplified structure. Accordingly, the substrate transfer apparatus 100 may sequentially transfer the substrate G. For example, the substrate transfer apparatus 100 may transfer seven through eight carriers 130 at the same time.

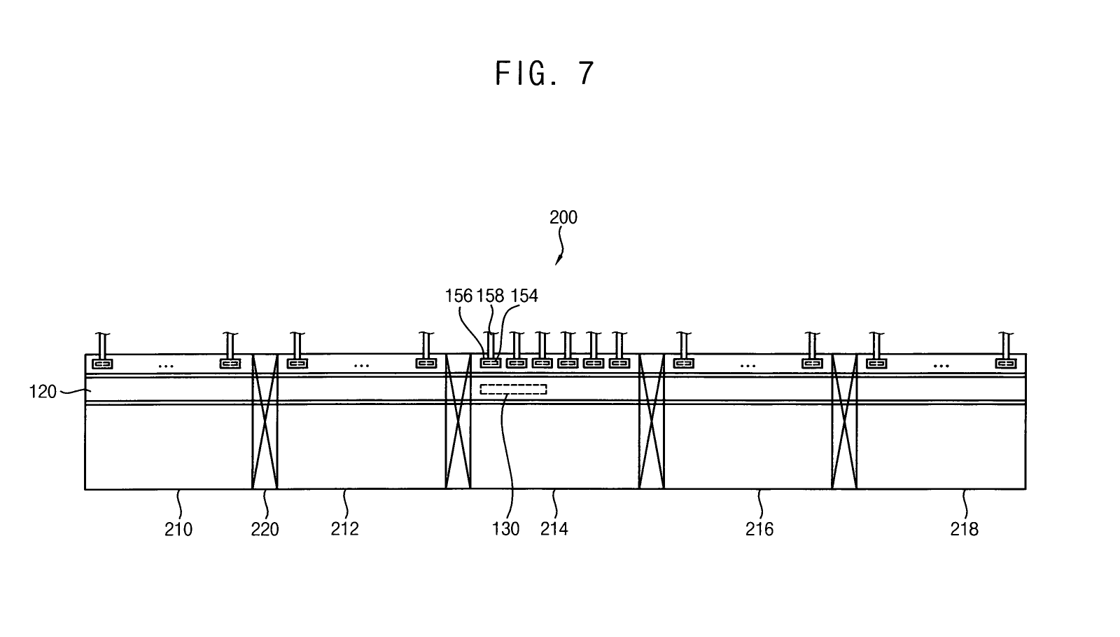

FIG. 7 is a side cross-sectional view illustrating an exemplary embodiment of a thin film deposition apparatus in accordance with the invention.

Referring to FIG. 7, a thin film deposition apparatus 200 may include a loading chamber 210, a first rotating chamber 212, a processing chamber 214, a second rotating chamber 216, an unloading chamber 218 and a substrate transfer apparatus 100. The loading chamber 210, the first rotating chamber 212, the processing chamber 214, the second rotating chamber 216 and the unloading chamber 218 may be arranged in a row (e.g., linearly) in the first direction. A gate 220 may locate between adjacent chambers. Here, the gate 220 may be opened and/or closed so that the carrier 130 of the substrate transfer apparatus 100 may be movable or restricted from moving through the gate 220. Whether the carrier 130 is moving through the open gate 220 or restricted from moving by the closed gate 220, a substrate G may be held or mounted on the carrier 130 of the substrate transfer apparatus 100.

A substrate G loaded the loading chamber 210 may be transferred to the first rotating chamber 212 to be primarily rotated, and then the substrate G may be transferred to the processing chamber 214. Here, the processing chamber 214 may be substantially the same as a chamber 110 illustrated in FIG. 1, and duplicated descriptions will be omitted.

A substrate G on which a thin film is formed by the processing chamber 214, and the carrier 130 to which the substrate G is mounted, may be transferred to the second rotating chamber 216 to be secondarily rotated, and then the substrate G may be transferred to the unloading chamber 218 such as to be unloaded. Such sequence may be considered a first or forward pass through the thin film deposition apparatus. For a second or reverse pass, the substrate G and the carrier 130 on which the substrate G is mounted may be sequentially transferred from the unloading chamber 218, the second rotating chamber 216, the processing chamber 214, the first rotating chamber 212 and loading chamber 210. The first and second passes may be repeated to repeatedly perform a thin film deposition process on the substrate G.

As illustrated in FIGS. 1 and 7, a substrate transfer apparatus 100 may include a guide rail 120, a carrier 130, a magnetic levitation unit 140 and a transferring unit 150. The substrate transfer apparatus 100 may sequentially and reversely repeatedly transfer the substrate G to the loading chamber 210, the first rotating chamber 212, the processing chamber 214, the second rotating chamber 216 and the unloading chamber 218 using a carrier 130 on which the substrate G is loaded. That is, a same substrate transfer apparatus 100 may be used to transfer the substrate G to the various chambers of the thin film deposition apparatus 200.

In an exemplary embodiment, for example, the guide rail 120 may extend in a same direction in which the loading chamber 210, the first rotating chamber 212, the processing chamber 214, the second rotating chamber 216 and the unloading chamber 218 are arranged. In addition, the second transferring magnetic materials 154 of the transferring unit 150 may be spaced apart from each other by a predetermined distance D along the guide rail 120.

Thus, the thin film deposition apparatus 200 may transfer the substrate G to the various chambers arranged in a row using the substrate transfer apparatus 100. Therefore, the thin film deposition apparatus 200 may accurately sequentially transfer the substrate G. As a result, the thin film deposition apparatus 200 may deposit a thin film on the substrate G accurately transferred by the substrate transfer apparatus 100.

Exemplary embodiments of the invention may be employed for any of a number of electronic devices including a display device manufactured by a substrate transfer apparatus and a thin film deposition apparatus. As a display device, for example, the organic light emitting display device may be used in a notebook computer, a laptop computer, a digital camera, a video camcorder, a cellular phone, a smart phone, a smart pad, a portable multimedia player (“PMP”), a personal digital assistant (“PDA”), a MP3 player, a navigation system, a television, a computer monitor, a game console, a video phone, etc.

The foregoing is illustrative of exemplary embodiments and is not to be construed as limiting thereof. Although a few exemplary embodiments have been described, those skilled in the art will readily appreciate that many modifications are possible in the exemplary embodiments without materially departing from the novel teachings and advantages of the invention. Accordingly, all such modifications are intended to be included within the scope of the invention as defined in the claims. Therefore, it is to be understood that the foregoing is illustrative of various exemplary embodiments and is not to be construed as limited to the specific exemplary embodiments disclosed, and that modifications to the disclosed exemplary embodiments, as well as other exemplary embodiments, are intended to be included within the scope of the appended claims.

What is claimed is:

1. A substrate transfer apparatus comprising:
a guide rail in a vacuum evacuable chamber;
a carrier configured to linearly move along the guide rail and to which a substrate is mounted;
a magnetic levitation unit configured to generate a magnetic levitation force between the guide rail and the carrier; and
a transferring unit configured to generate a momentum for linearly transferring the carrier, the transferring unit comprising:
a plurality of first transferring magnetic material members on an upper surface of the carrier,
a plurality of second transferring magnetic material members above the carrier and spaced apart from the first transferring magnetic material members, and
a plurality of containers in which the plurality of second transferring magnetic material members is respectively disposed.

2. The substrate transfer apparatus of claim 1, wherein
the guide rail extends in a first direction and comprises a first rail, and a second rail spaced apart from the first rail in a second direction perpendicular to the first direction, the first and second rails defining a space in which the carrier linearly moves along the guide rail, and
each of the first and the second rails comprises first protrusion portions spaced apart in a third direction perpendicular to the first and second directions, and a first recess portion defined between the spaced apart first protrusion portions, each of the first protrusion portions and the first recess portion extended in the first direction.

3. The substrate transfer apparatus of claim 2, wherein
the carrier comprises:
first side second protrusion portions protruded towards the first rail, and adjacent to each other in the third direction,
second side second protrusion portions protruded towards the second rail, and adjacent to each other in the third direction, and
first and second side second recess portions defined between the adjacent first side second protrusion portions and the adjacent second side second protrusion portions, respectively,
each of the second protrusion portions and the second recess portions extended in the first direction,
a first side second protrusion portion and a second side second protrusion portion of the carrier engages with the first recess portion of the first rail and the first recess portion of the second rail, respectively, and
the first side second recess portion and the second side second recess portion of the carrier engages with a first protrusion portion of the first rail and a first protrusion portion of the second rail, respectively.

4. The substrate transfer apparatus of claim 3, wherein the carrier further comprises:
a carrier body, and
a substrate plate which is in a lower portion of the carrier body and holds the substrate.

5. The substrate transfer apparatus of claim 3, wherein
the first protrusion portions of the guide rail overlap the second protrusion portions of the carrier, and
the magnetic levitation unit comprises:
a plurality of first levitating magnetic material members respectively in the first protrusion portions of the guide rail, and
a plurality of second levitating magnetic material members respectively in the second protrusion portions of the carrier and respectively facing the plurality of first levitating magnetic material members in the guide rail.

6. The substrate transfer apparatus of claim 5, wherein each of the first levitating magnetic material members comprises stainless steel.

7. The substrate transfer apparatus of claim 5, wherein each of the second levitating magnetic material members comprises an electromagnet or a permanent magnet.

8. The substrate transfer apparatus of claim 5, wherein the magnetic levitation unit further comprises a first sensor which is in the guide rail and configured to control a relative position between the first levitating magnetic material members and the second levitating magnetic material members.

9. The substrate transfer apparatus of claim 1, wherein the transferring unit further comprises a piping member which is connected to a container among the plurality of containers, extended to an outside of the chamber and configured to maintain the container at atmospheric pressure.

10. The substrate transfer apparatus of claim 9, further comprising a wiring which is connected to the second transferring magnetic material member in the container, via the piping member, and through which a driving power is applied to the second transferring magnetic material member in the container from an external power supply.

11. The substrate transfer apparatus of claim 1, wherein the transferring unit further comprises a second sensor which is in a container among the plurality of containers and configured to control a relative position between the first transferring magnetic material members and the second transferring magnetic material members.

12. The substrate transfer apparatus of claim 1, wherein each of the first transferring magnetic material members comprises a permanent magnet.

13. The substrate transfer apparatus of claim 12, wherein the first transferring magnetic material members have different polarities.

14. The substrate transfer apparatus of claim 1, wherein each of the second transferring magnetic material members comprises an electromagnet.

15. The substrate transfer apparatus of claim 1, wherein
the second transferring magnetic material members are spaced apart from each other along the guide rail and in the first direction, and
the carrier overlaps three second transferring magnetic material members in the first direction, in a top plan view.

16. A thin film deposition apparatus comprising:
a processing chamber configured to be vacuum evacuable and define a space in which a thin film is deposited on a substrate;
a guide rail in the processing chamber and extended in a first direction;
a carrier configured to carry the substrate and linearly move along the guide rail;
a magnetic levitation unit configured to generate a magnetic levitation force between the guide rail and the carrier; and
a transferring unit configured to generate a momentum for linearly transferring the carrier, the transferring unit comprising:
a plurality of first transferring magnetic material members on an upper surface of the carrier,
a plurality of second transferring magnetic material members above the carrier and spaced apart from the first transferring magnetic material members, and
a plurality of containers in which the plurality of second transferring magnetic material members is disposed, respectively.

17. The thin film deposition apparatus of claim 16, further comprising:
a loading chamber in which the substrate is loaded into the thin film deposition apparatus, the loading chamber coupled to the processing chamber; and
an unloading chamber from which the substrate is unloaded from the thin film deposition apparatus, the unloading chamber coupled to the processing chamber.

18. The thin film deposition apparatus of claim 16, wherein the transferring unit further comprises a piping member which is connected to a container among the plurality of containers, extended to an outside of the processing chamber and maintains the container at atmospheric pressure.

19. The thin film deposition apparatus of claim 18, further comprising a wiring which is connected to the second transferring magnetic material member in the container, via the piping member, and through which a driving power is applied to the second transferring magnetic material member in the container from an external power supply.

20. The thin film deposition apparatus of claim 16, wherein
the second transferring magnetic material members are spaced apart from each other along the guide rail and in the first direction, and
the carrier overlaps three second transferring magnetic material members in the first direction, in a top plan view.
